(19) United States
(12) Patent Application Publication
(10) Pub. No.: US 2011/0260760 A1
(43) Pub. Date: Oct. 27, 2011

(54) VOLTAGE CONTROL OSCILLATOR AND CONTROL METHOD THEREOF

(76) Inventor: Pei-Si WU, Kao Hsiung City (TW)

(21) Appl. No.: 13/090,598

(22) Filed: Apr. 20, 2011

(30) Foreign Application Priority Data
Apr. 21, 2010 (TW) 099112450

(51) Int. Cl. H03L 7/08; H03L 7/06

(52) U.S. Cl. 327/148; 327/147

(57) ABSTRACT

A voltage control oscillator and a control method thereof is disclosed in the invention. The voltage control oscillator increases frequency of an output frequency as a control signal is increased under a first mode. The voltage control oscillator decreases frequency of the output frequency as a control signal is increased under a second mode.

This application claims the benefit of the filing date of Taiwan Application Ser. No. 099112450, filed on Apr. 21, 2010, the content of which is incorporated herein by reference.

### BACKGROUND

(a) Technical Field

The invention relates to a voltage control oscillator, particularly to a voltage control oscillator with a wide adjustable frequency range and a control method thereof.

(b) Description of the Related Art

FIG. 1A is a schematic diagram of a conventional phase lock loop (PLL) circuit. The phase lock loop 10 includes a phase detector 11, a charge pump 12, a loop filter 13, a voltage control oscillator (VCO) 14, and a frequency divider 15.

Generally speaking, the control mechanism of the voltage control oscillator 14 is required to operate with large range of bandwidth and voltage. However, it is difficult to design an accurate control mechanism for large range of bandwidth and voltage, and the larger the range, the more interference, hence cause the bad property of whole device.

The voltage control oscillator 14 generates an output frequency Fvco according to a control voltage Vc. The bandwidth of the voltage control oscillator 14 is determined by the range of the output frequency. The voltage range of the voltage control oscillator 14 is determined by the range of the control voltage Vc. Thus the bandwidth and the voltage range of the voltage control oscillator 14 can be represented by a slope Kvco of a line. The slope Kvco is defined as the output frequency Fvco over the control voltage Vc. Therefore, in order to reduce the effect of large bandwidth and large voltage range of the voltage control oscillator 14, the voltage control oscillator 14 is designed to operate within a plurality of bands with the same slope Kvco, as shown in FIG. 1B. In FIG. 1B, it is divided into eight bands B0˜B07. Each band contains a fixed bandwidth, and the voltage control oscillator 14 can switch to different band according to required frequency.

Referring to the frequency fvco0 shown in FIG. 1B, the voltage control oscillator 14 may switch to band B0, B1 or B2 to generate frequency fvco0, where the bands B0, B1 and B2 are corresponding to the control voltages Vc0, Vc1, and Vc2, respectively. However, bands of the voltage control oscillator 14 can be affected by the environmental factors, such as temperature variation. For example, the band B2 is drifted to B2′ and the band B1 is drifted to BF due to the environmental influence, however, the voltage control oscillator 14 scan not generate the frequency fvco0 by band B2′. Hence the number of usable bands for voltage control oscillator 14 is reduced, the phase lock loop circuit 10 has to switch to the band B1′ to correctly generate the frequency fvco0.

Therefore, the conventional voltage control oscillator may output an unacceptable frequency during a band switching period.

### BRIEF SUMMARY OF THE INVENTION

One object of the present invention is to provide a voltage control oscillator and the control method thereof to increase the bandwidth of the adjustable frequency range.

One object of the present invention is to provide a voltage control oscillator and the control method thereof to increase the precision of frequency locking.

Another object of the present invention is to provide a voltage control oscillator and the control method thereof to speed up frequency locking.

One embodiment of the present invention provides a voltage control oscillator, including a voltage control oscillator and a plurality of regulation units. The voltage control oscillator generates an output frequency according to a control voltage and a first selection signal wherein the voltage control oscillator includes a first oscillation unit and a second oscillation unit. The first oscillation unit increases the output frequency according to the selection of the first selection signal as the control voltage is increased; and the second oscillation unit for decreasing the output frequency according to the selection of the first selection signal as the control voltage is increased. Further a number of the regulation units coupling to the voltage control oscillator are determined by the selection of a second selection signal so as to adjust the output frequency. Under a first mode, the voltage control oscillator selects the first oscillation unit according to the first selection signal. Under a second mode, the voltage control oscillator selects the second oscillation unit according to the first selection signal.

Furthermore, an embodiment of the invention provides a method for controlling a voltage control oscillator. The method comprises the following steps. At first, a control voltage is received and an output frequency is generated. Then, a first mode of the voltage control oscillator is provided. As the received control voltage is increased, the frequency of the output frequency is determined to be increased or not according to whether a selection signal selects the first mode or not. A second mode of the voltage control oscillator is provided. As the received control voltage is increased, the frequency of the output frequency is determined to be decreased or not according to whether a selection signal selects the second mode or not.

The embodiments of the voltage control oscillator and the control method thereof determine gain of the voltage control oscillator according a selection signal and adjust the output frequency to a desired value. Thus widening the adjustable frequency range of the voltage control oscillator can be accomplished. Since the adjustable frequency range is wider, there are more selections to lock a desired frequency by the voltage control oscillator. Thus the problem in the prior art can be solved and the environmental influence can be overcome.

### BRIEF DESCRIPTION OF THE DRAWINGS

FIG. 1A shows a schematic diagram illustrating a conventional phase lock loop (PLL) device according to the prior art.

FIG. 1B shows a waveform diagram illustrating a conventional band configuration.

FIG. 2A shows a schematic diagram illustrating an embodiment of a voltage control oscillator.

FIG. 2B shows an embodiment of a band configuration.

FIG. 3A shows a schematic diagram illustrating an embodiment of a phase lock loop.

FIG. 3B shows a schematic diagram illustrating an embodiment of a voltage control oscillator.

FIG. 3C shows a schematic diagram illustrating an embodiment of a phase lock loop.

FIG. 3D shows a schematic diagram illustrating an embodiment of a phase lock loop.

FIG. 3E shows a schematic diagram illustrating an embodiment of a phase lock loop.

FIG. 4 shows a flow chart illustrating an embodiment of a control method applicable to a voltage control oscillator.

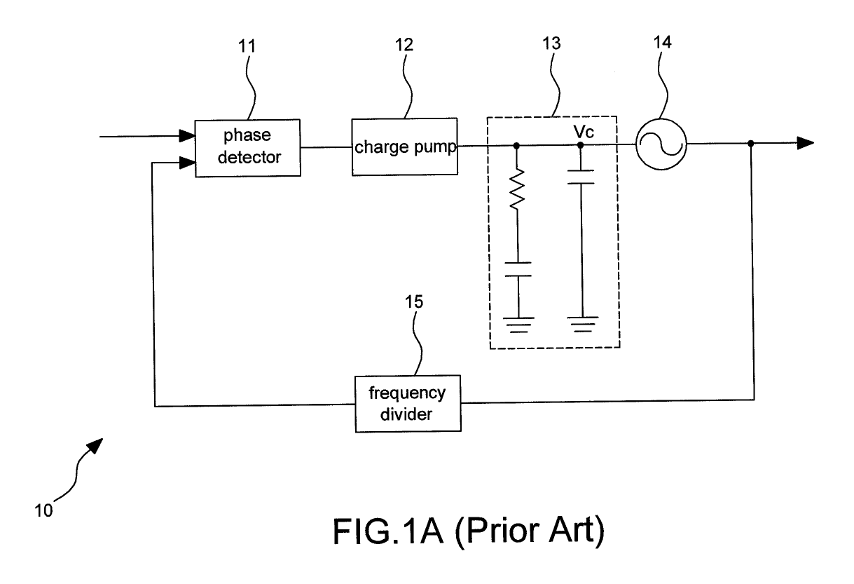

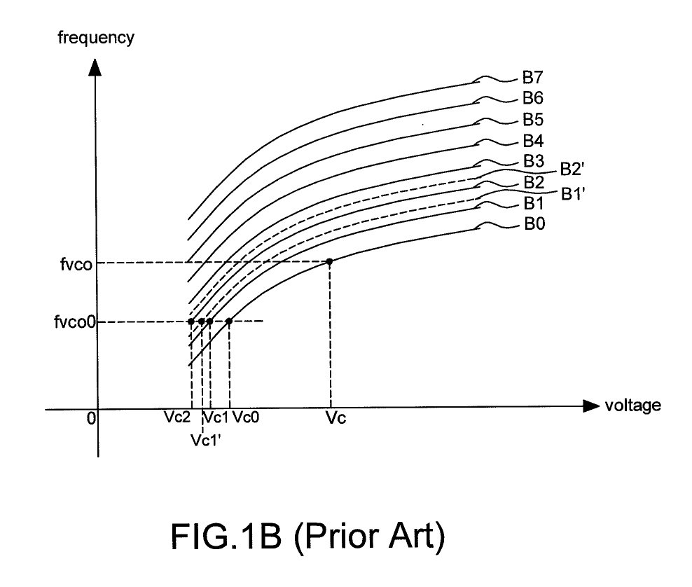

### DETAILED DESCRIPTION OF THE INVENTION

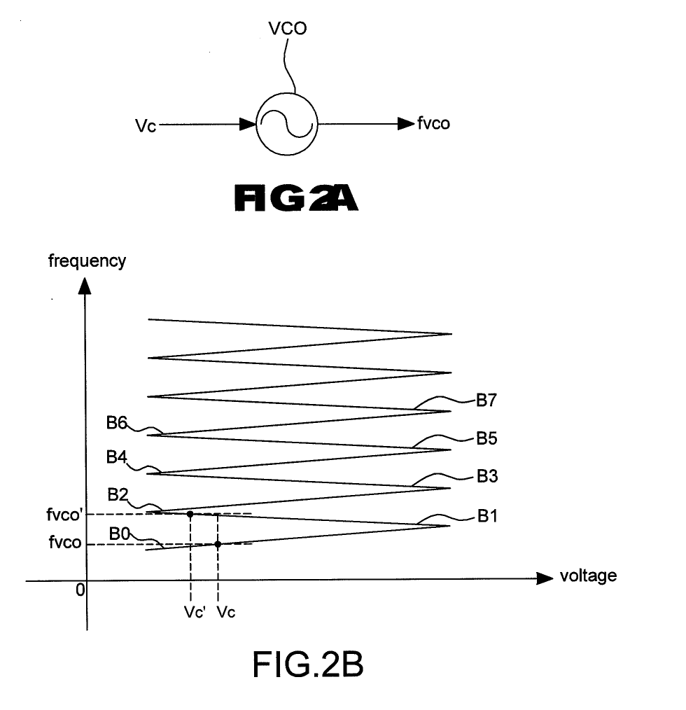

FIG. 2A is a schematic diagram of an embodiment of a voltage control oscillator VCO. The voltage control oscillator VCO generates an output phase lock frequency fvco according to a control voltage Vc. The output frequency fvco is in relation to the control voltage Vc.

In an embodiment, the voltage control oscillator VCO includes a first mode and a second mode. Under the first mode, as the control voltage Vc received by the voltage control oscillator VCO is increased, the voltage control oscillator VCO increases the output frequency fvco; and, as the control voltage Vc received by the voltage control oscillator VCO is decreased, the voltage control oscillator VCO decreases the output frequency fvco. Under the second mode, as the control voltage Vc received by the voltage control oscillator VCO is increased, the voltage control oscillator VCO decreases the output frequency fvco; and, as the control voltage Vc received by the voltage control oscillator VCO is decreased, the voltage control oscillator VCO increases the output frequency fvco.

It should be noted that as shown in FIG. 2B the bandwidth of an embodiment of the voltage control oscillator VCO includes a plurality of bands. For example, the first mode includes a plurality of first bands B0, B2, B4, B6 . . . etc. and the second mode includes a plurality of second bands B1, B3, B5, B7 . . . etc. In another embodiment, the first bands and the second bands can be set in a manner of alternating permutation or continuous permutation. For example, the second bands B1, B3, B5, B7 . . . follow the first bands B0, B2, B4, B6 . . . . Please note that the ratio of the control voltage to the output frequency fvco is defined as the gain. The gain may be familiar as a slope Kvco by the ordinary skilled in the art. The gain of the first bands of the voltage control oscillator VCO is positive and the gain of the second bands is negative.

Since the embodiment of the band distribution of the voltage control oscillator VCO includes a wider frequency range, the voltage control oscillator VCO has more choices to switch band to rapidly lock an output frequency to a desired frequency. As shown in FIG. 2B, if a desired output frequency fvco is needed to be generated by the voltage control oscillator VCO, the voltage control oscillator VCO can switch band to a usable band B0 to generate the desired output frequency fvco corresponding to a control voltage Vc. For example, if the band B0 is drifted to the band B1 due to the environmental influence, the voltage control oscillator VCO can adjust the control voltage from Vc to Vc′ to lock the frequency fvco′ in the band B1. Therefore, the voltage control oscillator VCO can easy lock to a desired frequency according to the embodiment of band distribution During band switching, the output frequency of the voltage control oscillator VCO can obtain an expected frequency. Thus the unexpected output problem made by the conventional voltage control oscillator can be solved and the environmental influence can be overcome by the embodiment.

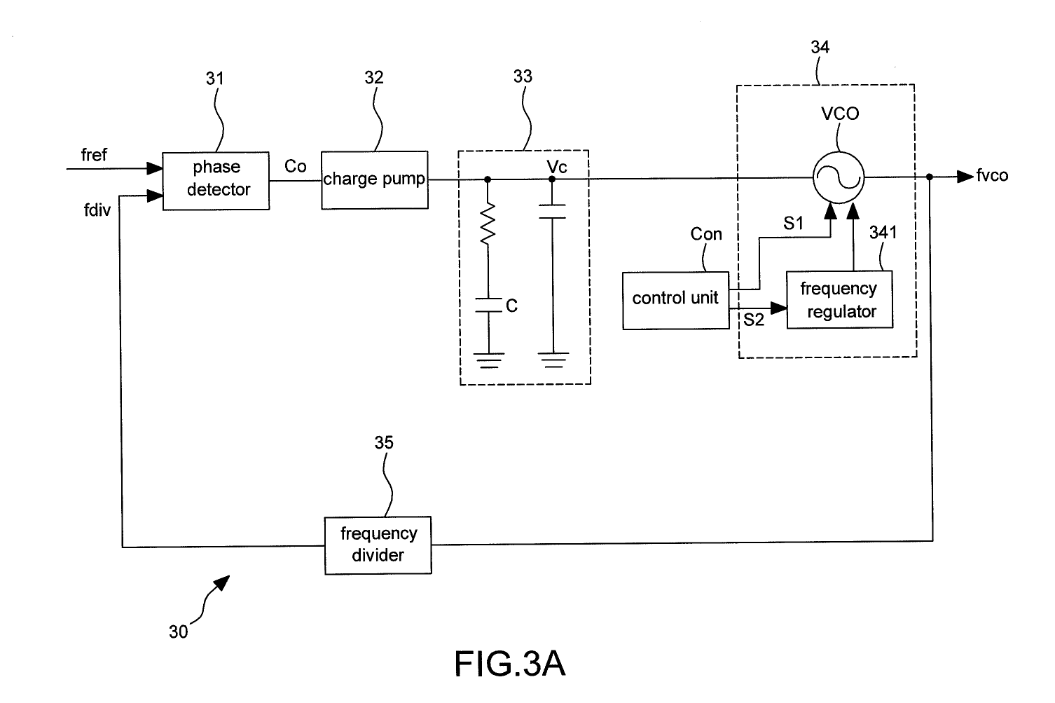

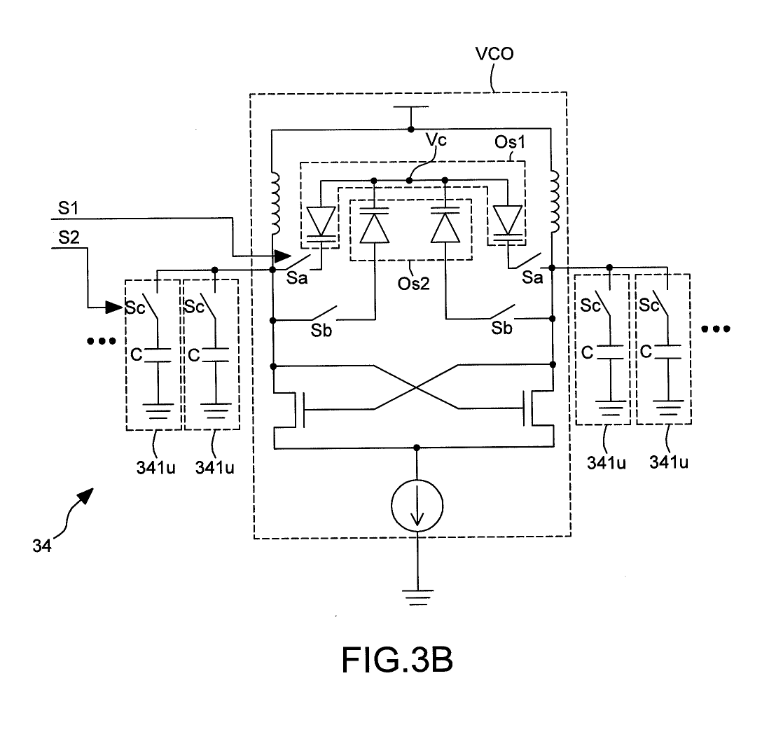

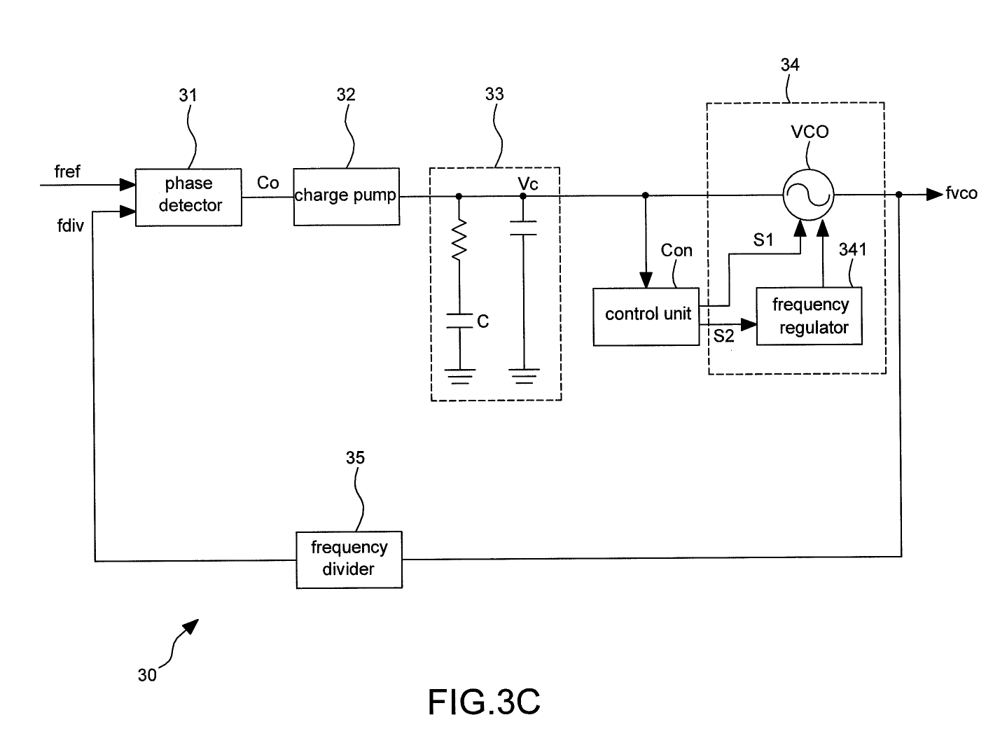

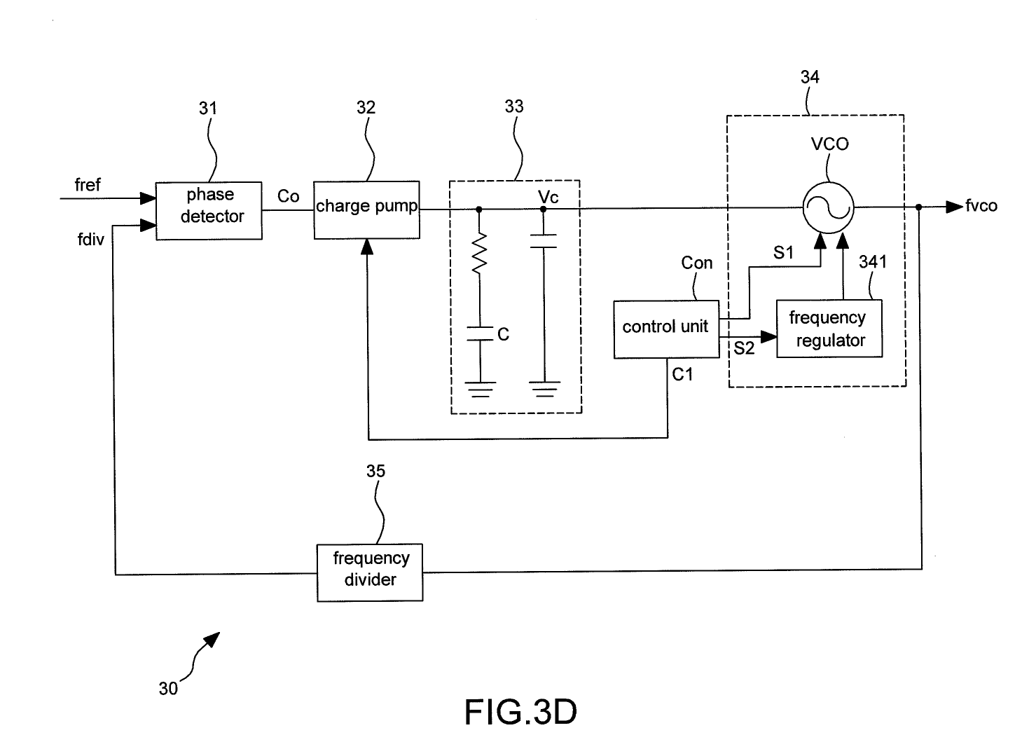

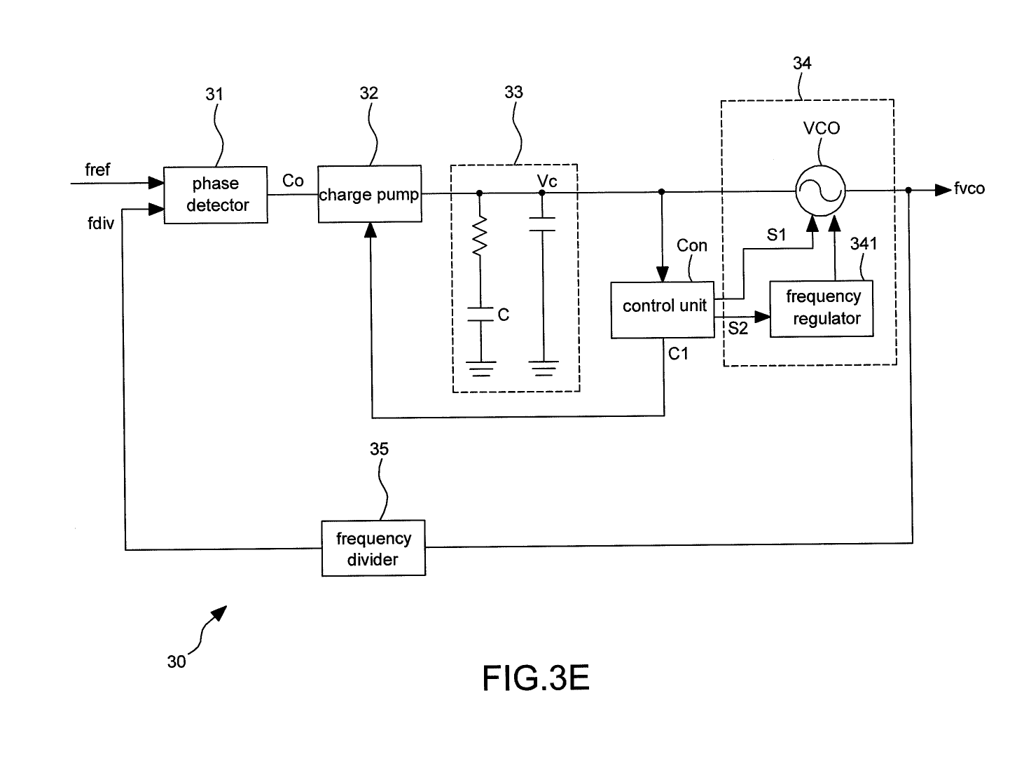

FIG. 3A is a schematic diagram of an embodiment of a phase lock loop 30. The phase lock loop 30 includes a phase detector 31, a charge pump 32, a loop filter 33, a voltage control oscillation circuit 34, and a frequency divider 35.

As shown in FIG. 3A, the phase detector 31 detects a phase difference between an input signal fref and a divided frequency fdiv divided by the frequency divider 35 and outputs a control signal Co to control the charge pump 32 according to the phase difference. The output frequency fvco is divided to generate the divided frequency fdiv. For example, if the phase of the divided frequency fdiv leads that of the input signal fref, the phase detector 31 generates a control signal Co to decrease an output current of the charge pump 32. Further the loop filter 33 decreases the control voltage Vc according to the decreased current to decrease the output frequency fvco of the voltage control oscillation circuit 34. On the contrary, if the phase of the divided frequency fdiv lags that of the input signal fref, the phase detector 31 generates the control signal Co to increase an output current of the charge pump 32. Further the loop filter 33 increases the control voltage Vc according to the increased current to increase the output frequency fvco of the voltage control oscillation circuit 34.

The phase lock loop 30 generates an output frequency fvco having a stable frequency according to the control voltage Vc. Please note that the embodiment of the phase detector 31, the charge pump 32, the loop filter 33, and the frequency divider 35 may be implemented by current available technology or future technology. In an embodiment, the frequency divider 35 may be omitted.

In an embodiment, the voltage control oscillation circuit 34 includes a voltage control oscillator VCO and a frequency regulator 341. A band of the voltage control oscillator VCO is selected by a first selection signal S1 and a second selection signal S2. Then the voltage control oscillator VCO generates an output frequency fvco according to the control signal Vc on the band.

The frequency regulator 341 includes at least a regulation unit. The first selection signal S1 and the second selection signal S2 may be provided externally or generated by a control unit Con to determine a band of the voltage control oscillation circuit 34.

FIG. 3B is a schematic diagram of an embodiment of the voltage control oscillation circuit in FIG. 3A. The voltage control oscillation circuit 34 includes a first oscillation unit Os1 and a second oscillation unit Os2, a plurality of regulation units 341u and a voltage control oscillator VCO. In an embodiment, each regulation unit includes a switch Sc and a capacitor C. Please note that a gain of the voltage control oscillator VCO is a ratio of the control signal Vc to the output frequency fvco. Referring to FIGS. 3A and 3B collectively, the frequency regulator 341 selectively couples the regulation units 341u to the voltage control oscillator VCO according to the second selection signal S2. The selection of coupling a number of regulation units 341u to the voltage control oscillator VCO can determine the gain of the voltage control oscillator VCO. Thus the voltage control oscillator VCO can adjust its gain by the above selection.

The voltage control oscillator VCO controls the switches Sa and Sb to select one of the oscillation units Os1 and Os2 to be coupled according to the first selection signal S1. Further the voltage control oscillation circuit 34 includes at least two modes, a first mode and a second mode. Under the first mode, the voltage control oscillator VCO turns on the switch Sa and turns off the switch Sb to select the first oscillation unit Os1 to be coupled to the voltage control oscillator VCO. The voltage control oscillator VCO can increase the output frequency fvco following to the increasing of the control voltage Vc. Thus the first bands B0, B2, B4, B6 . . . having positive gain shown in FIG. 2B may be generated by the voltage control oscillator VCO. Under the second mode, the voltage control oscillator VCO turns off the switch Sa and turns on the switch Sb to select the second oscillation unit Os2 to be coupled to the voltage control oscillator VCO. The voltage control oscillator VCO can decrease the output frequency fvco following to the increasing of the control voltage Vc. Thus the second bands B1, B3, B5, B7 . . . having negative gain shown in FIG. 2B may be generated by the voltage control oscillator VCO.

Please refer to FIGS. 2B, 3A, and 3B collectively. If the voltage control oscillation circuit 34 operates under the first mode at the band B0, the voltage control oscillation circuit 34 turns on the two switches Sa and turns off the two switches Sb according to first selection signal S1, thereby selecting the first oscillation unit Os1 to couple to the voltage control oscillator VCO. Thus the ratio of the output frequency fvco to the control voltage Vc (that is, gain KVCO) is positive in the band B0, as shown in FIG. 2B. In the meanwhile the voltage control oscillation circuit 34 drives the switch Sc to select a preset number of regulation units 341u to couple to the voltage control oscillator VCO according to the second selection signal S2. Therefore the voltage control oscillator VCO can output frequency fvco at the band B0 with a positive gain (Kvco).

In an embodiment, if the voltage control oscillation circuit 34 switches band to the band B1, the voltage control oscillation circuit 34 turns off the two switches Sa and turns on the two switches Sb according to the first selection signal S1. Thus the voltage control oscillator VCO can couple to the second oscillation unit Os2. In the meantime the voltage control oscillation circuit 34 drives the switch Sc to select a preset number of regulation units 341u to couple to the voltage control oscillator VCO according to the second selection signal S2 Therefore the voltage control oscillator VCO can output frequency fvco at the band B1 with a negative gain (Kvco)

Since the voltage control oscillation circuit 34 determines the gain of the voltage control oscillator VCO and adjust the output frequency fvco according to the selection signals S1 and S2, the phase lock loop 30 can lock frequency to a preset value at the bands distribution like a spring form shown in FIG. 2B. In this manner, embodiments of the voltage control oscillation circuit 34 can operate in unlimited control voltage range and frequency range as long as the control voltage and the bands distribution is well set. Therefore the embodiments of the voltage control oscillation circuit 34 have more selections to lock frequency. Thus the problem in the prior art can be solved to overcome the environmental influence and achieve the effect of rapidly locking frequency to a preset value.

In an embodiment, referring to FIG. 3A, the control unit Con may include an analog-to-digital converter (ADC). The ADC can determine a time to switch bands or whether to switch bands or not. Referring to FIG. 3B, the first oscillation unit Os1 and the second oscillation unit Os2 each include two variable capacitors. The first oscillation unit Os1 and the second oscillation unit Os2 may implement by various current or future oscillating elements.

In an embodiment of the phase lock loop shown in the FIG. 3C, the control unit Con further detects a control voltage Vc. The control voltage Vc is used as a reference to generate the selection signal.

In an embodiment of the phase lock loop shown in the FIG. 3D, the charge pump 32 operate s in relation to the control unit Con during the control unit Con switches bands. For example, the control unit Con may generate a control signal C1 to control the charge pump 32. Thus The control signal C1 makes the voltage control method of the charge pump 32 correspond to and the band switching operation of the control unit con. Further the control means of the phase lock loop in FIG. 3C and FIG. 3D can be combined in use, as shown in FIG. 3E. One of ordinary skill in the art should understand how to implement that and thus the details will not be given hereinafter.

It should be noted that the above voltage control oscillator is implemented by capacitors but in another embodiment can be implemented by other elements, for example, inductor or other capacitive elements including semiconductor elements, etc. Besides, in another embodiment, the band distribution means as shown in FIG. 2B can be designed as follows: the odd number bands B1, B3, B5 . . . decrease the frequency with the increase of the control voltage, and the even number bands B0, B2, B4 . . . increase the frequency with the increase of the control voltage. The configuration of the bands can be switched or designed according to the needs of a designer. For example, each of the N bands (N is larger than 1 and smaller than infinity) uses the first mode and each of the M bands (M is larger than 1 but not equal to N and smaller than infinity) uses the second mode. Furthermore, in another embodiment, the voltage control oscillator can be implemented by the various current or future voltage control oscillators including at least two different oscillation units having different oscillation characteristics.

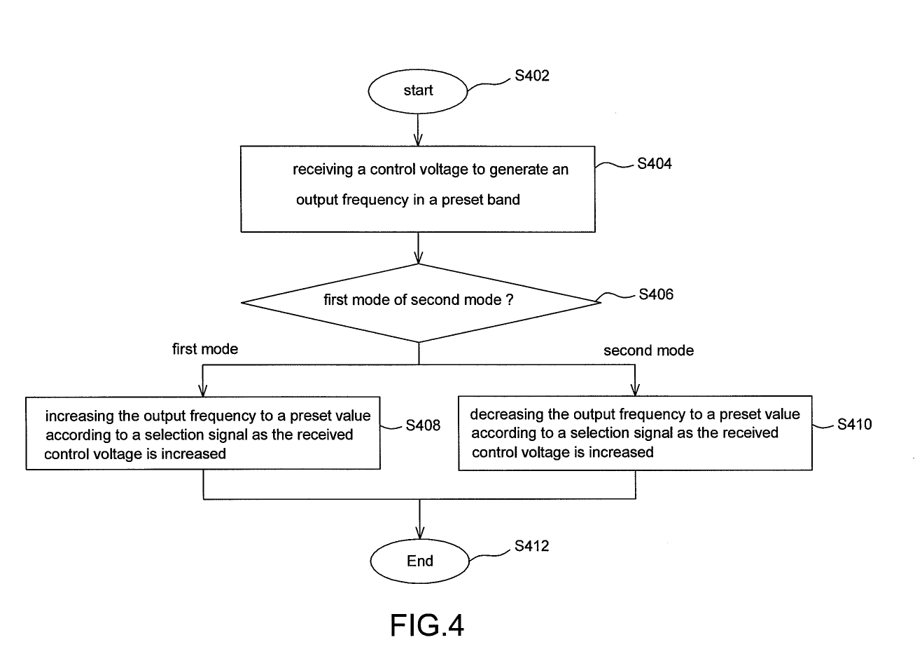

FIG. 4 is a flow chart of an embodiment of a control method applicable to the analog voltage control. The method includes the following steps. After the step S402 starts, enter the step S404: at first receiving a control voltage to generate an output frequency in a preset band. Then, in the step S406, it is determined whether to select the first mode or the second mode. The method and timing of selecting the two modes can be designed according to the needs of a designer.

When the voltage control oscillator selects the first mode, enter the step S408. The operation of this mode is to increase the output frequency to a preset value according to a selection signal as the received control voltage is increased. Thus the output frequency can be adjusted to the preset value.

When the voltage control oscillator selects the second mode, enter the step S410. The operation of this mode is to decrease the output frequency to a preset value according to a selection signal as the received control voltage is increased. Thus the frequency of the output frequency is adjusted to the preset value. Following that enter the step S412: end.

Although the present invention has been fully described by the above embodiments, the embodiments should not constitute the limitation of the scope of the invention. Various modifications or changes can be made by those who are skilled in the art without deviating from the scope of the claimed invention.

What is claimed is:

1. A voltage control oscillation circuit, comprising:
a voltage control oscillator for generating an output frequency according to a control voltage and a first selection signal, the output frequency is related to the control voltage, the voltage control oscillator comprises:
a first oscillation unit for increasing the output frequency according to the selection of the first selection signal as the control voltage is increased; and
a second oscillation unit for decreasing the output frequency according to the selection of the first selection signal as the control voltage is increased;
and
a plurality of regulation units, a number of the regulation units coupling to the voltage control oscillator is determined by the selection of a second selection signal so as to adjust the output frequency;
wherein the first oscillation unit is selected according to the first selection signal under a first mode, and the second oscillation unit is selected according to the first selection signal under a second mode.

2. The circuit according to claim 1, further comprising a control unit for generating the first selection signal and the second selection signal.

3. The circuit according to claim 1, wherein the first mode comprises a plurality of first bands having a positive Kvco and the second mode comprises a plurality of second bands having a negative Kvco, and the first bands and the second bands are allocated in a manner of alternating distribution.

4. The circuit according to claim 1, wherein each of the first oscillation unit and the second oscillation unit comprises two variable capacitors.

5. The circuit according to claim 1, wherein each of the regulation units comprises a capacitor.

6. A voltage control oscillation circuit, comprising:
a voltage control oscillator for generating an output frequency according to a control voltage and a first selection signal wherein the ratio of the control voltage to the output frequency is defined as a gain, the voltage control oscillator comprises:
a first oscillation unit for increasing the output frequency according to the selection of the first selection signal as the control voltage is increased, so as to generate the gain in positive; and
a second oscillation unit for decreasing the output frequency according to the selection of the first selection signal as the control voltage is increased, so as to generate the gain in negative;
and
a plurality of regulation units, a number of the regulation units coupling to the voltage control oscillator is determined by the selection of a second selection signal so as to operate in relation to the first oscillation unit or the second oscillation unit for adjusting the output frequency.

7. The circuit according to claim 6, further comprising a control unit for generating the first selection signal so that determining to select the first oscillation unit or the second oscillation unit, and generating the second selection signal so that determining how to select the regulation units.

8. The circuit according to claim 6, wherein each of the first oscillation unit and the second oscillation unit comprises two variable capacitors.

9. The circuit according to claim 6, wherein each of the regulation units comprises a capacitor.

10. A phase lock loop device, comprising:
a phase detector for detecting a phase difference between an input signal and an output frequency and generating a control signal according to the phase difference;
a charge pump coupled to the phase detector, for generating a control current according to the control signal;
a loop filter coupled to the charge pump, generating a control voltage according to the control current; and
a voltage control oscillation circuit coupled to the loop filter, generating an output frequency according to the control voltage, wherein the output frequency is related to the control voltage, the voltage control oscillation circuit comprises:
a voltage control oscillator for generating the output frequency according to the control voltage and the first selection signal, the ratio of the control voltage to the output frequency is defined as a gain;
a first oscillation unit for increasing the output frequency according to the selection of the first selection signal as the control voltage is increased; and
a second oscillation unit, for decreasing the output frequency according to the selection of the first selection signal as the control voltage is increased;
and
a plurality of regulation units selectively coupling to the voltage control oscillator;
wherein the first oscillation unit is selected according to the first selection signal as the control signal is increased under a first mode, and the second oscillation unit is selected according to the first selection signal as the control signal is increased under a second mode.

11. The device according to claim 10, wherein the voltage control oscillator further comprises a control unit for generating the first selection signal to determine the gain is positive or negative.

12. The device according to claim 11, wherein the control unit generates a second selection signal to determine a number of the regulation units coupling to the voltage control oscillator so as to adjust the output frequency.

13. The device according to claim 10, wherein the first mode comprises a plurality of first bands having a positive Kvco, the second mode comprises a plurality of second bands having a negative Kvco, and the first bands and the second bands are allocated in a manner of alternating distribution.

14. The device according to claim 13, wherein the first bands and the second bands are allocated in a manner of continuous distribution.

15. The device according to claim 10, wherein the gain is positive when the first selection signal selects the first oscillation unit, and the gain is negative when the first selection signal selects the second oscillation unit.

16. The device according to claim 11, wherein the control unit further generates another control signal to the charge pump to adjust the magnitude of the control current generated by the charge pump under the first mode and the second mode.

17. The device according to claim 10, wherein each of the first oscillation unit and the second oscillation unit comprises two variable capacitors.

18. The device according to claim 10, wherein each of the regulation units comprises a capacitor.
